(19) United States
(12) Patent Application Publication
(10) Pub. No.: US 2020/0209755 A1
(43) Pub. Date: Jul. 2, 2020

(54) MIRROR FOR EXTREME ULTRAVIOLET LIGHT AND EXTREME ULTRAVIOLET LIGHT GENERATING APPARATUS

(71) Applicant: Gigaphoton Inc., Tochigi (JP)

(72) Inventors: Yoshiyuki HONDA, Oyama-shi (JP); Osamu WAKABAYASHI, Oyama-shi (JP)

(73) Assignee: Gigaphoton Inc., Tochigi (JP)

(21) Appl. No.: 16/814,584

(22) Filed: Mar. 10, 2020

Related U.S. Application Data
(63) Continuation of application No. PCT/JP2017/037993, filed on Oct. 20, 2017.

(51) Int. Cl. G03F 7/20; G21K 1/06; G02B 5/08

(52) U.S. Cl. CPC G03F 7/2008; G02B 5/0875; G02B 5/0891; G21K 1/062

(57) ABSTRACT

A mirror for extreme ultraviolet light includes: a substrate (41); a multilayer film (42) provided on the substrate and configured to reflect extreme ultraviolet light; and a capping layer (53) provided on the multilayer film, and the capping layer includes a first layer (61) containing a compound of a metal having lower electronegativity than Ti and a non-metal and having a lower density than TiO₂, and a second layer (62) arranged between the first layer and the multilayer film and having a higher density than the first layer.

### CROSS-REFERENCE TO RELATED APPLICATIONS

The present application is a continuation application of International Application No. PCT/JP2017/037993, filed on Oct. 20, 2017, the entire contents of which are hereby incorporated by reference.

### BACKGROUND

### 1. Technical Field

The present disclosure relates to a mirror for extreme ultraviolet light and an extreme ultraviolet light generating apparatus.

### 2. Related Art

Recently, miniaturization of semiconductor processes has involved increasing miniaturization of transfer patterns for use in photolithography of the semiconductor processes. In the next generation, microfabrication at 20 nm or less will be required. Thus, development of an exposure device is expected including a combination of an apparatus for generating extreme ultraviolet (EUV) light having a wavelength of about 13 nm and reduced projection reflection optics.

Three types of extreme ultraviolet light generating apparatuses have been proposed: an LPP (Laser Produced Plasma) type apparatus using plasma generated by irradiating a target substance with a laser beam, a DPP (Discharge Produced Plasma) type apparatus using plasma generated by discharge, and an SR (Synchrotron Radiation) type apparatus using synchrotron radiation light.

### LIST OF DOCUMENTS

### Patent Documents

Patent Document 1: Japanese Unexamined Patent Application Publication No. 2006-173446

Patent Document 2: International Patent Publication No. 2005/091887

Patent Document 3: Japanese Unexamined Patent Application Publication No. 2007-198782

Patent Document 4: US Published Patent Application No. 2016/0349412

### SUMMARY

A mirror for extreme ultraviolet light according to one aspect of the present disclosure may include: a substrate; a multilayer film provided on the substrate and configured to reflect extreme ultraviolet light; and a capping layer provided on the multilayer film. The capping layer may include a first layer containing a compound of a metal having lower electronegativity than Ti and a non-metal and having a lower density than TiO₂, and a second layer arranged between the first layer and the multilayer film and having a higher density than the first layer.

An extreme ultraviolet light generating apparatus according to one aspect of the present disclosure may include: a chamber; a droplet discharge unit configured to discharge a droplet of a target substance into the chamber; and a mirror for extreme ultraviolet light provided in the chamber. The mirror for extreme ultraviolet light may include a substrate, a multilayer film provided on the substrate and configured to reflect extreme ultraviolet light, and a capping layer provided on the multilayer film. The capping layer may include a first layer containing a compound of a metal having lower electronegativity than Ti and a non-metal and having a lower density than TiO₂, and a second layer arranged between the first layer and the multilayer film and having a higher density than the first layer.

### BRIEF DESCRIPTION OF THE DRAWINGS

With reference to the accompanying drawings, some embodiments of the present disclosure will be described below merely by way of example.

FIG. 1 diagrammatically shows a schematic exemplary configuration of an entire extreme ultraviolet light generating apparatus.

FIG. 2 diagrammatically shows a section of an EUV light reflective mirror of a comparative example.

FIG. 3 diagrammatically shows an estimated mechanism of a reaction between a gas supplied to a reflective surface and fine particles adhering to the reflective surface.

FIG. 4 diagrammatically shows an estimated mechanism of accumulation of fine particles of a target substance.

FIG. 5 diagrammatically shows a section of an EUV light reflective mirror of Embodiment 1.

FIG. 6 diagrammatically shows a section of an EUV light reflective mirror of Embodiment 2.

### DESCRIPTION OF EMBODIMENTS

1. Overview
2. Description of extreme ultraviolet light generating apparatus

2.1 Overall configuration

2.2 Operation
3. Description of EUV light reflective mirror of comparative example

3.1 Configuration

3.2 Problem
4. Description of EUV light reflective mirror of Embodiment 1

4.1 Configuration

4.2 Effect
5. Description of EUV light reflective mirror of Embodiment 2

5.1 Configuration

5.2 Effect

Now, with reference to the drawings, embodiments of the present disclosure will be described in detail.

The embodiments described below illustrate some examples of the present disclosure, and do not limit contents of the present disclosure. Also, all configurations and operations described in the embodiments are not necessarily essential as configurations and operations of the present disclosure.

The same components are denoted by the same reference numerals, and overlapping descriptions are omitted.

### 1. Overview

Embodiments of the present disclosure relate to a mirror used in an extreme ultraviolet light generating apparatus configured to generate light having a wavelength of extreme ultraviolet (EUV) light. Hereinafter, the extreme ultraviolet light is sometimes referred to as EUV light.

### 2. Description of Extreme Ultraviolet Light Generating Apparatus

2.1 Overall Configuration

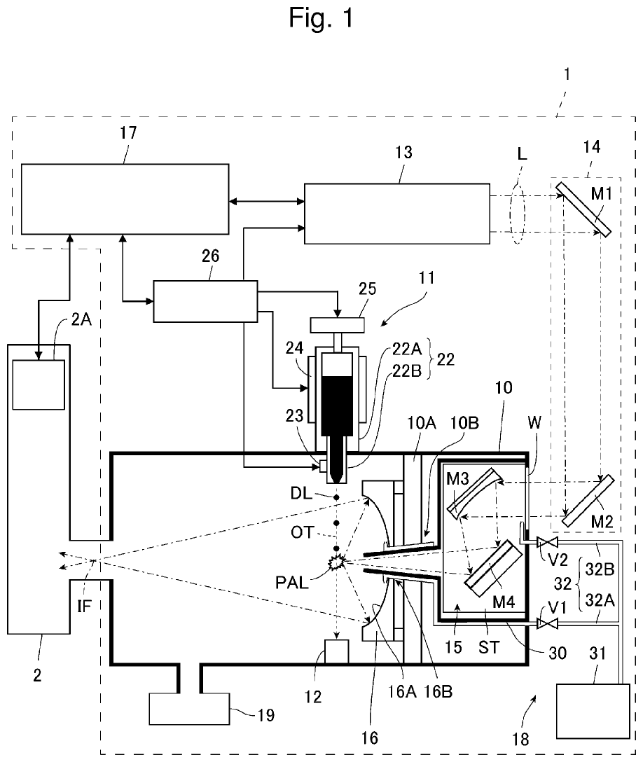

FIG. 1 diagrammatically shows a schematic exemplary configuration of an entire extreme ultraviolet light generating apparatus. As shown in FIG. 1, an extreme ultraviolet light generating apparatus 1 of this embodiment is used together with an exposure device 2. The exposure device 2 exposes a semiconductor wafer to EUV light generated by the extreme ultraviolet light generating apparatus 1, and includes a control unit 2A. The control unit 2A outputs a burst signal to the extreme ultraviolet light generating apparatus 1. The burst signal designates a burst period for generating the EUV light and an intermission period for stopping generation of the EUV light. For example, a burst signal to alternately repeat the burst period and the intermission period is output from the control unit 2A of the exposure device 2 to the extreme ultraviolet light generating apparatus 1.

The extreme ultraviolet light generating apparatus 1 includes a chamber 10. The chamber 10 is a container that can be sealed and reduced in pressure. A wall of the chamber 10 has at least one through-hole. The through-hole is closed by a window W. The window W is configured to transmit a laser beam L entering from outside the chamber 10. The chamber 10 may be divided by a partition plate 10A.

The extreme ultraviolet light generating apparatus 1 also includes a droplet discharge unit 11. The droplet discharge unit 11 is configured to discharge a droplet DL of a target substance into the chamber 10. The droplet discharge unit 11 may include, for example, a target ejector 22, a piezoelectric element 23, a heater 24, a pressure adjusting unit 25, and a droplet generation control unit 26.

The target ejector 22 includes a tank 22A removably mounted to the wall of the chamber 10, and a nozzle 22B connected to the tank 22A. The tank 22A stores the target substance. A material of the target substance may include tin, terbium, gadolinium, lithium, or xenon, or any combinations of two or more of them, but not limited thereto. At least a tip of the nozzle 22B is arranged in the chamber 10.

The piezoelectric element 23 is provided on an outer surface of the nozzle 22B of the target ejector 22. The piezoelectric element 23 is driven by power supplied from the droplet generation control unit 26, and vibrates at predetermined vibration intervals. The heater 24 is provided on an outer surface of the tank 22A of the target ejector 22. The heater 24 is driven by the power supplied from the droplet generation control unit 26, and heats the tank 22A of the target ejector 22 so as to reach a preset temperature. The preset temperature may be set by the droplet generation control unit 26, or by an input device outside the extreme ultraviolet light generating apparatus 1. The pressure adjusting unit 25 adjusts a gas supplied from a gas cylinder (not shown) to gas pressure designated by the droplet generation control unit 26. The gas at the gas pressure presses the molten target substance stored in the tank 22A of the target ejector 22.

A droplet-related signal is input to the droplet generation control unit 26. The droplet-related signal indicates information relating to the droplet DL such as a speed or a direction of the droplet DL. The droplet generation control unit 26 controls the target ejector 22 to adjust a discharge direction of the droplet DL based on the droplet-related signal. The droplet generation control unit 26 controls the pressure adjusting unit 25 to adjust the speed of the droplet DL based on the droplet-related signal. The control of the droplet generation control unit 26 is merely exemplary, and different control may be added as required.

The extreme ultraviolet light generating apparatus 1 further includes a droplet collecting unit 12. The droplet collecting unit 12 is configured to collect a droplet DL that has not been turned into plasma in the chamber 10 among droplets DL supplied into the chamber 10. For example, the droplet collecting unit 12 is provided on a trajectory OT of the droplet DL on a wall of the chamber 10 opposite to a wall to which the droplet discharge unit 11 is mounted.

The extreme ultraviolet light generating apparatus 1 further includes a laser unit 13, a beam transmission optical system 14, a laser beam condensing optical system 15, and an EUV light reflective mirror 16. The laser unit 13 emits a laser beam L having a predetermined pulse width. The laser unit 13 includes, for example, a solid-state laser or a gas laser. The solid-state laser includes, for example, an Nd:YAG laser, an Nd:YVO₄ laser, or a laser that outputs harmonic light thereof. The gas laser includes, for example, a CO₂ laser or an excimer laser.

The beam transmission optical system 14 is configured to transmit the laser beam L emitted from the laser unit 13 to the window W of the chamber 10. The beam transmission optical system 14 may include, for example, a plurality of mirrors M1, M2 configured to reflect the laser beam L. In the example in FIG. 1, two mirrors are provided, but one mirror or three or more mirrors may be provided. An optical element other than the mirror such as a beam splitter may be used.

The laser beam condensing optical system 15 is provided in the chamber 10 and is configured to focus, in a plasma generating region PAL, the laser beam L having entered the chamber 10 through the window W. In the plasma generating region PAL, the droplet DL is turned into plasma. The laser beam condensing optical system 15 may include, for example, a concave mirror M3 configured to reflect the laser beam L having entered the chamber 10 and to focus and guide the laser beam L in a reflecting direction, and a mirror M4 configured to reflect the laser beam L from the concave mirror M3 toward the plasma generating region PAL. The laser beam condensing optical system 15 may include a stage ST movable in three axial directions, and the stage ST may be moved to adjust a focusing position.

The EUV light reflective mirror 16 is a mirror for EUV light provided in the chamber 10 and configured to reflect EUV light generated when the droplet DL is turned into plasma in the plasma generating region PAL in the chamber 10. The EUV light reflective mirror 16 includes, for example, a spheroidal reflective surface that reflects the EUV light generated in the plasma generating region PAL, and is configured so that a first focal point is located in the plasma generating region PAL and a second focal point is located in an intermediate focal point IF. The EUV light reflective mirror 16 may have a through-hole 16B extending from a surface 16A that reflects the EUV light to a surface opposite to the surface 16A and including a central axis of the EUV light reflective mirror 16. The laser beam L emitted from the laser beam condensing optical system 15 may pass through the through-hole 16B. The central axis of the EUV light reflective mirror 16 may be a line passing through the first focal point and the second focal point or may be a rotation axis of a spheroid. When the chamber 10 is divided by the partition plate 10A as described above, the EUV light reflective mirror 16 may be secured to the partition plate 10A. In this case, the partition plate 10A may have a communication hole 10B communicating with the through-hole 16B in the EUV light reflective mirror 16. The EUV light reflective mirror 16 may include a temperature adjustor to maintain the EUV light reflective mirror 16 at a substantially constant temperature.

The extreme ultraviolet light generating apparatus 1 further includes an EUV light generation controller 17. The EUV light generation controller 17 generates the droplet-related signal based on a signal output from a sensor (not shown), and outputs the generated droplet-related signal to the droplet generation control unit 26 of the droplet discharge unit 11. The EUV light generation controller 17 also generates a light emission trigger signal based on the droplet-related signal and the burst signal output from the exposure device 2, and outputs the generated light emission trigger signal to the laser unit 13, thereby controlling a burst operation of the laser unit 13. The burst operation means an operation of emitting a continuous pulse laser beam L at predetermined intervals during a burst-on period and preventing emission of the laser beam L during a burst-off period. The control of the EUV light generation controller 17 is merely exemplary, and different control may be added as required. The EUV light generation controller 17 may perform the control of the droplet generation control unit 26.

The extreme ultraviolet light generating apparatus 1 further includes a gas supply unit 18. The gas supply unit 18 is configured to supply a gas, which reacts with fine particles generated when the droplet DL is turned into plasma, into the chamber 10. The fine particles include neutral particles and charged particles. When the material of the target substance stored in the tank 22A of the droplet discharge unit 11 is tin, the gas supplied from the gas supply unit 18 is a hydrogen gas or a gas containing hydrogen. In this case, tin fine particles are generated when the droplet DL of the target substance is turned into plasma, and the tin fine particles react with the hydrogen to generate stannane that is gas at room temperature. The gas supply unit 18 may include, for example, a cover 30, a gas storing unit 31, and a gas introducing pipe 32.

In the example in FIG. 1, the cover 30 is provided to cover the laser beam condensing optical system 15, and includes a truncated conical nozzle. The nozzle of the cover 30 is inserted through the through-hole 16B in the EUV light reflective mirror 16, and a tip of the nozzle protrudes from the surface 16A of the EUV light reflective mirror 16 and is directed toward the plasma generating region PAL. The gas storing unit 31 stores the gas that reacts with the fine particles generated when the droplet DL is turned into plasma. The gas introducing pipe 32 introduces the gas stored in the gas storing unit 31 into the chamber 10. As in the example in FIG. 1, the gas introducing pipe 32 may be divided into a first gas introducing pipe 32A and a second gas introducing pipe 32B.

In the example in FIG. 1, the first gas introducing pipe 32A is configured to adjust, with a flow regulating valve V1, a flow rate of the gas flowing from the gas storing unit 31 through the first gas introducing pipe 32A. In the example in FIG. 1, an output end of the first gas introducing pipe 32A is arranged along an outer wall surface of the nozzle of the cover 30 inserted through the through-hole 16B in the EUV light reflective mirror 16, and an opening of the output end is directed toward the surface 16A of the EUV light reflective mirror 16. Thus, the gas supply unit 18 can supply the gas along the surface 16A of the EUV light reflective mirror 16 toward an outer edge of the EUV light reflective mirror 16. In the example in FIG. 1, the second gas introducing pipe 32B is configured to adjust, with a flow regulating valve V2, a flow rate of the gas flowing from the gas storing unit 31 through the second gas introducing pipe 32B. In the example in FIG. 1, an output end of the second gas introducing pipe 32B is arranged in the cover 30, and an opening of the output end is directed toward an inner surface of the window W of the chamber 10. Thus, the gas supply unit 18 can introduce the gas along an inner surface of the chamber 10 at the window W, and supply the gas from the nozzle of the cover 30 toward the plasma generating region PAL.

The extreme ultraviolet light generating apparatus 1 further includes an exhaust unit 19. The exhaust unit 19 is configured to exhaust a residual gas in the chamber 10. The residual gas contains the fine particles generated when the droplet DL is turned into plasma, a product generated by the reaction between the fine particles and the gas supplied from the gas supply unit 18, and an unreacted gas. The exhaust unit 19 may maintain the inside of the chamber 10 at substantially constant pressure.

2.2 Operation

The gas supply unit 18 supplies, into the chamber 10, the gas that reacts with the fine particles generated when the droplet DL is turned into plasma. The exhaust unit 19 maintains the inside of the chamber 10 at substantially constant pressure. The pressure in the chamber 10 is, for example, within the range of 20 to 100 Pa, preferably 15 to 40 Pa.

In this state, the EUV light generation controller 17 controls the droplet discharge unit 11 to discharge the droplet DL of the target substance into the chamber 10, and controls the laser unit 13 to perform the burst operation. A diameter of the droplet DL supplied from the droplet discharge unit 11 to the plasma generating region PAL is, for example, 10 to 30 μm.

The laser beam L emitted from the laser unit 13 is transmitted to the window W of the chamber 10 by the beam transmission optical system 14, and enters the chamber 10 through the window W. The laser beam L having entered the chamber 10 is focused in the plasma generating region PAL by the laser beam condensing optical system 15, and is applied to at least one droplet DL having reached the plasma generating region PAL from the droplet discharge unit 11. The droplet DL irradiated with the laser beam L is turned into plasma, and light including EUV light is radiated from the plasma. The EUV light is selectively reflected by the reflective surface of the EUV light reflective mirror 16 and is emitted to the exposure device 2. A plurality of laser beams may be applied to one droplet DL.

When the droplet DL is turned into plasma to generate the fine particles as described above, the fine particles are dispersed in the chamber 10. One part of the fine particles dispersed in the chamber 10 move toward the nozzle of the cover 30 of the gas supply unit 18. When the gas introduced from the second gas introducing pipe 32B of the gas supply unit 18 moves from the nozzle of the cover 30 toward the plasma generating region PAL as described above, the fine particles dispersed in the plasma generating region PAL can be prevented from entering the cover 30. Even if the fine particles enter the cover 30, the gas introduced from the second gas introducing pipe 32B reacts with the fine particles, thereby preventing the fine particles from adhering to the window W, the concave mirror M3, the mirror M4, or the like.

Another part of the fine particles dispersed in the chamber 10 move toward the surface 16A of the EUV light reflective mirror 16. The fine particles moving toward the surface 16A of the EUV light reflective mirror 16 react with the gas supplied from the gas supply unit 18 to generate a predetermined product. As described above, when the gas supply unit 18 supplies the gas along the surface 16A of the EUV light reflective mirror 16, the gas and the fine particles can more efficiently react with each other than when no gas is supplied along the surface 16A.

When the material of the target substance is tin and the gas supplied from the gas supply unit 18 contains hydrogen as described above, the tin fine particles react with the hydrogen to generate stannane that is gas at room temperature as described above. However, stannane is easily dissociated from hydrogen at high temperature to generate tin fine particles. Thus, when the product is stannane, the EUV light reflective mirror 16 is preferably maintained at a temperature of 60° C. or lower to prevent dissociation from hydrogen. The temperature of the EUV light reflective mirror 16 is more preferably 20° C. or lower.

The product obtained by the reaction with the gas supplied from the gas supply unit 18, together with an unreacted gas, flows in the chamber 10. At least part of the product and the unreacted gas flowing in the chamber 10 flow, as a residual gas, into the exhaust unit 19 on an exhaust flow of the exhaust unit 19. The residual gas having flowed into the exhaust unit 19 is subjected to a predetermined exhaust process such as detoxification in the exhaust unit 19. This prevents the fine particles or the like generated when the droplet DL is turned into plasma from accumulating on the surface 16A of the EUV light reflective mirror 16 or the like. This also prevents the fine particles or the like from remaining in the chamber 10.

### 3. Description of EUV Light Reflective Mirror of Comparative Example

Next, an EUV light reflective mirror of a comparative example of the extreme ultraviolet light generating apparatus will be described. Components similar to those described above are denoted by the same reference numerals, and overlapping descriptions are omitted unless otherwise stated.

3.1 Configuration

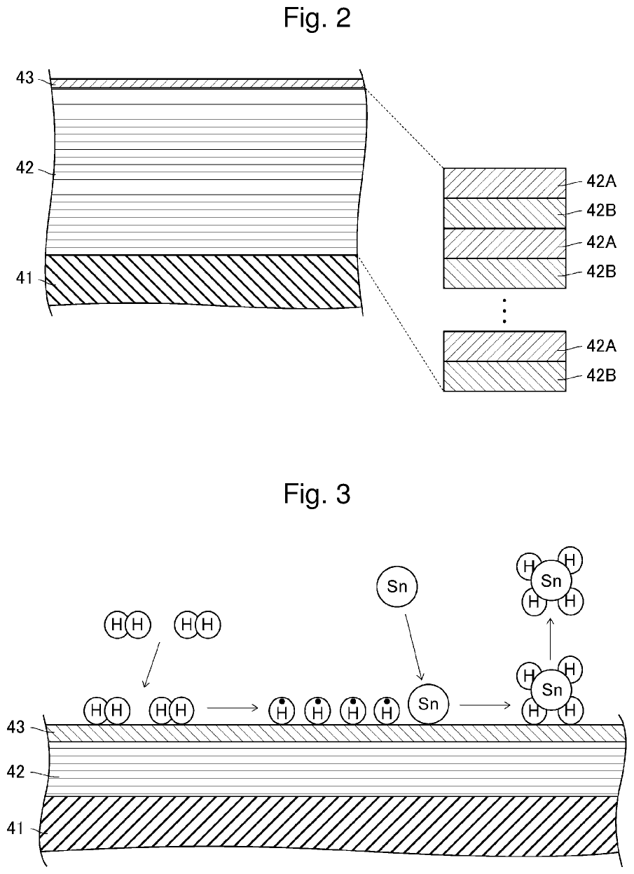

FIG. 2 diagrammatically shows a section of an EUV light reflective mirror 16 of a comparative example. As shown in FIG. 2, the EUV light reflective mirror 16 of the comparative example includes a substrate 41, a multilayer film 42, and a capping layer 43.

The multilayer film 42 reflects EUV light and is provided on the substrate 41. The multilayer film 42 includes a first layer 42A containing a first material and a second layer 42B containing a second material alternately stacked. A reflective surface of the EUV light reflective mirror 16 includes an interface between the first layer 42A and the second layer 42B of the multilayer film 42, and a surface of the multilayer film 42. The surface of the multilayer film 42 is an interface between the multilayer film 42 and the capping layer 43. As long as the multilayer film 42 reflects the EUV light, the first material and the second material are not limited. For example, the first material may be Mo and the second material may be Si, or the first material may be Ru and the second material may be Si. Alternatively, for example, the first material may be Be and the second material may be Si, or the first material may be Nb and the second material may be Si. Alternatively, for example, the first material may be Mo and the second material may be RbSiH₃, or the first material may be Mo and the second material may be RbₓSi_{y}.

The capping layer 43 protects the multilayer film 42. A material of the capping layer 43 is, for example, TiO₂. The material of the capping layer 43 may be other than TiO₂.

3.2 Problem

Among fine particles generated when a droplet DL is turned into plasma, fine particles moving toward a surface of the capping layer 43 that is a surface 16A of the EUV light reflective mirror 16 react with a gas supplied from a gas supply unit 18 to generate a predetermined product as described above. An estimated mechanism of this reaction is shown in FIG. 3. FIG. 3 shows a case where a material of a target substance is tin and the gas supplied from the gas supply unit 18 contains hydrogen.

As shown in FIG. 3, when the gas supplied from the gas supply unit 18 contains hydrogen molecules, the hydrogen molecules are adsorbed on the surface of the capping layer 43. When the hydrogen molecules are irradiated with light including EUV light, the hydrogen molecules generate hydrogen radicals. The fine particles moving toward the surface 16A of the EUV light reflective mirror 16 react with the hydrogen radicals to generate stannane that is gas at room temperature as expressed by Expression (1) below:

Sn+4H.→SnH₄ (1)

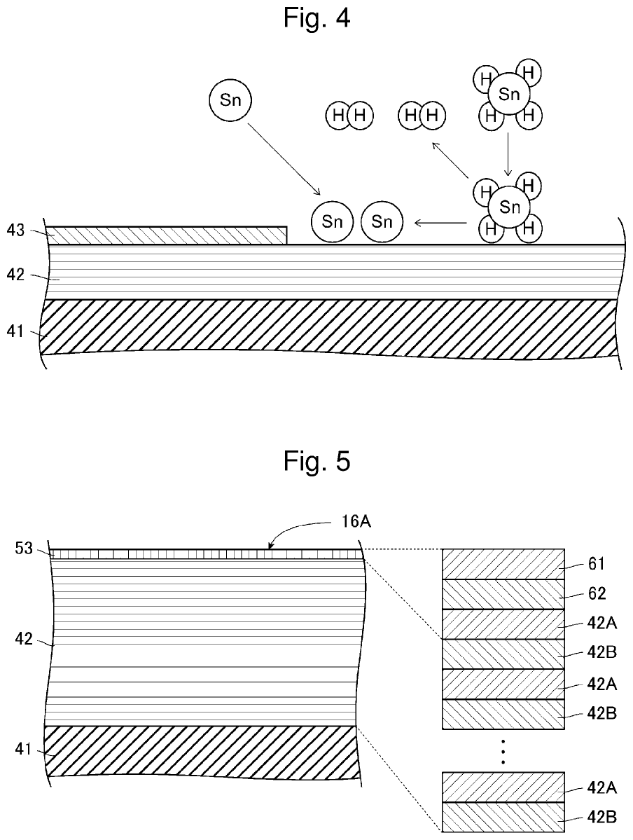

However, the fine particles may collide with and wear away the capping layer 43 to locally expose the multilayer film 42 from the capping layer 43. In this case, the fine particles easily accumulate on the multilayer film 42. An estimated mechanism of accumulation of the fine particles of the target substance is shown in FIG. 4. Like FIG. 3, FIG. 4 shows a case where the material of the target substance is tin and the gas supplied from the gas supply unit 18 contains hydrogen.

As shown in FIG. 4, when the multilayer film 42 is exposed from the capping layer 43, the stannane is adsorbed on the multilayer film 42. When the stannane is adsorbed, a reverse reaction of Expression (1) occurs, and the hydrogen molecules are released from the stannane to generate tin fine particles, which remain on the multilayer film 42. When the stannane is further adsorbed on the tin fine particles remaining on the multilayer film 42, the reverse reaction of Expression (1) occurs, and further tin fine particles remain on the tin fine particles remaining on the multilayer film 42. In this way, the tin fine particles accumulate on the multilayer film 42. Although such a mechanism is an estimation as described above, an experiment has shown that the fine particles easily accumulate on the multilayer film 42 exposed from the capping layer 43.

An experiment has also shown that the fine particles may accumulate on the surface of the capping layer 43 before the surface is worn away by collision with the fine particles, or on a new surface resulting from the wearing away of the surface of the capping layer 43. A reason for this may be that the fine particles accumulate on the surface of the capping layer 43 at high speed and the reverse reaction predominates over the reaction of Expression (1). Another reason may be that a concentration of the stannane is high near the surface of the capping layer 43 and the reverse reaction predominates over the reaction of Expression (1). A further reason may be that a surface temperature of the capping layer 43 increases and thus the reverse reaction predominates over the reaction of Expression (1).

In this way, the fine particles may accumulate on the surface of the capping layer 43 or on the multilayer film 42 exposed from the capping layer 43. In this case, the accumulating fine particles may reduce reflectance of the EUV light on the EUV light reflective mirror 16.

Then, embodiments described below illustrate an EUV light reflective mirror 16 that can prevent a reduction in reflectance of EUV light.

### 4. Description of EUV Light Reflective Mirror of Embodiment 1

Next, a configuration of an EUV light reflective mirror 16 of Embodiment 1 will be described. Components similar to those described above are denoted by the same reference numerals, and overlapping descriptions are omitted unless otherwise stated. A case where a material of a target substance is tin and a gas supplied from a gas supply unit 18 contains hydrogen will be described below as an example.

4.1 Configuration

FIG. 5 diagrammatically shows a section of the EUV light reflective mirror 16 of Embodiment 1. As shown in FIG. 5, the EUV light reflective mirror 16 of this embodiment is different from the EUV light reflective mirror 16 of the comparative example in that the former includes a capping layer 53 including a plurality of layers while the latter includes the capping layer 43 including a single layer. The capping layer 53 of this embodiment transmits EUV light, and includes a first layer 61 and a second layer 62.

The first layer 61 contains a compound of a metal having lower electronegativity than Ti and a non-metal and has a lower density than TiO₂. The metal having lower electronegativity than Ti may include, for example, group 2 elements other than Be, and alkali metals. The compound may include, for example, a boride of the group 2 element, a nitride of the group 2 element, or an oxide of the group 2 element. Generally, transmittance of the EUV light through a boride is higher than transmittance of the EUV light through a nitride, and transmittance of the EUV light through the nitride is higher than transmittance of the EUV light through an oxide. Thus, in terms of higher transmittance of the EUV light, the nitride of the group 2 element is more preferable than the oxide of the group 2 element, and the boride of the group 2 element is more preferable than the nitride of the group 2 element. The compound is not limited to the boride, the nitride, or the oxide. A density of TiO₂ is 4.23 g/cm³, and thus the density of the first layer 61 is lower than the density of TiO₂. As long as the first layer 61 contains the compound of the metal having lower electronegativity than Ti and the non-metal and has the lower density than TiO₂, the first layer 61 may contain, together with the compound, additives or impurities in a smaller amount than the compound. The first layer 61 preferably contains the compound of the metal having lower electronegativity than Ti and the non-metal at a higher composition ratio than other materials. The first layer 61 preferably contains a compound of at least one metal selected from Mg, Ca, or Sc and a non-metal in terms of easily releasing electrons and easily generating hydrogen radicals. The compound may include, for example, MgO, CaO, and Sc₂O₃ as oxides. A density of MgO is 3.58 g/cm³. A density of CaO is 3.35 g/cm³. A density of Sc₂O₃ is 3.86 g/cm³. The compound may include, for example, Mg₃N₂ and Ca₃N₂ as nitrides. A density of Mg₃N₂ is 2.71 g/cm³. A density of Ca₃N₂ is 2.67 g/cm³. The compound may include, for example, MgB₂ and CaB₆ as borides. A density of MgB₂ is 2.57 g/cm³. A density of CaB₆ is 2.45 g/cm³. The compound contained in the first layer 61 may have an amorphous structure or a polycrystalline structure, but preferably has a polycrystalline structure when the compound is a photocatalyst.

A thickness of the first layer 61 is preferably, for example, equal to or larger than a thickness of a minimum structural unit of the compound contained in the first layer 61 and 5 nm or smaller. The thickness of the first layer 61 is preferably larger than a thickness of the second layer 62 in terms of preventing the first layer 61 from being worn away to expose the second layer 62 as compared to when the thickness of the first layer 61 is smaller than the thickness of the second layer 62. Herein, a thickness of a layer is obtained in such a manner that thicknesses at any three or more points of the layer are measured to obtain an arithmetic mean value of the measured thicknesses. Although TiO₂ does not correspond to the compound, a thickness of a minimum structural unit of TiO₂ is 0.2297 nm.

Surface roughness of the first layer 61 that is a surface 16A of the EUV light reflective mirror 16 is, for example, an Ra value of 0.5 nm or lower, and preferably 0.3 nm or lower. Surface roughness may be measured by, for example, a method described in APPLIED OPTICS Vol. 50, No. 9/20 March (2011) C164-C171.

The second layer 62 is arranged between the first layer 61 and the multilayer film 42, and has a higher density than the first layer 61. A different layer may be provided between the first layer 61 and the second layer 62, but as in the example in FIG. 5, the first layer 61 is preferably in contact with the second layer 62. A material of the second layer 62 is not particularly limited as long as the density of the second layer 62 is higher than the density of the first layer 61. The second layer 62 preferably contains a compound of a metal having lower electronegativity than Ti and a non-metal. In this case, the compound of the metal having lower electronegativity than Ti and the non-metal contained in the second layer 62 may have an amorphous structure or a polycrystalline structure. However, the compound preferably has a polycrystalline structure when the compound is a photocatalyst in terms of promoting a reaction between tin fine particles and hydrogen radicals. When the second layer 62 contains such a compound, the thickness of the second layer 62 is preferably equal to or larger than a thickness of a minimum structural unit of the compound and 5 nm or smaller.

The second layer 62 may contain, for example, at least one of a boride of a lanthanoid metal, a nitride of the lanthanoid metal, and an oxide of the lanthanoid metal. As long as the second layer 62 mainly contains such a material, the second layer 62 may contain, together with the main material, additives or impurities in a smaller amount than the main material. The second layer 62 preferably contains at least one of the boride of the lanthanoid metal, the nitride of the lanthanoid metal, and the oxide of the lanthanoid metal at a higher composition ratio than other materials. The lanthanoid metal may be selected from La or Ce. The oxide of the lanthanoid metal may include, for example, La₂O₃, CeO₂, Eu₂O₃, TmO₃, Gd₂O₃, Yb₂O₃, Pr₂O₃, Tb₂O₃, Lu₂O₃, Nd₂O₃, Dy₂O₃, Pm₂O₃, Ho₂O₃, Sm₂O₃, or Er₂O₃. Densities of these compounds are as described below. Specifically, the density of La₂O₃ is 6.51 g/cm³. The density of CeO₂ is 7.22 g/cm³. The density of Eu₂O₃ is 7.42 g/cm³. The density of TmO₃ is 8.6 g/cm³. The density of Gd₂O₃ is 7.41 g/cm³. The density of Yb₂O₃ is 9.17 g/cm³. The density of Pr₂O₃ is 6.9 g/cm³. The density of Tb₂O₃ is 7.9 g/cm³. The density of Lu₂O₃ is 9.42 g/cm³. The density of Nd₂O₃ is 7.24 g/cm³. The density of Dy₂O₃ is 7.8 g/cm³. The density of Pm₂O₃ is 6.85 g/cm³. The density of Ho₂O₃ is 8.41 g/cm³. The density of Sm₂O₃ is 8.35 g/cm³. The density of Er₂O₃ is 8.64 g/cm³. The nitride of the lanthanoid metal may include, for example, SmN, TmN, or YbN. A density of SmN is 7.353 g/cm³. A density of TmN is 9.321 g/cm³. A density of YbN is 6.57 g/cm³. The boride of the lanthanoid metal may include, for example, LaB₆, CeB₆, NdB₆, or SmB₆. A density of LaB₆ is 2.61 g/cm³. A density of CeB₆ is 4.8 g/cm³. A density of NdB₆ is 4.93 g/cm³. A density of SmB₆ is 5.07 g/cm³. As described above, in terms of higher transmittance of the EUV light, the nitride of the lanthanoid metal is more preferable than the oxide of the lanthanoid metal, and the boride of the lanthanoid metal is more preferable than the nitride of the lanthanoid metal. When the second layer 62 contains the compound of the lanthanoid metal as described above, the thickness of the second layer 62 is preferably equal to or larger than a thickness of a minimum structural unit of the compound and 5 nm or smaller.

The second layer 62 may contain at least one of a boride of a metal such as Y, Zr, Nb, Hf, Ta, W, Re, Os, Ir, Sr, or Ba, a nitride of the metals, and an oxide of the metals. As long as the second layer 62 mainly contains such a material, the second layer 62 may contain, together with the main material, additives or impurities in a smaller amount than the main material. The second layer 62 preferably contains at least one of the boride of the metal, the nitride of the metal, and the oxide of the metal at a higher composition ratio than other materials. The metal is preferably selected from Hf or Ta. The oxide of the metal may include Y₂O₃, ZrO₂, Nb₂O₅, HfO₂, Ta₂O₅, WO₂, ReO₃, OSO₄, IrO₂, SrO, or BaO. Densities of these compounds are as described below. Specifically, the density of Y₂O₃ is 5.01 g/cm³. The density of ZrO₂ is 5.68 g/cm³. The density of Nb₂O₅ is 4.6 g/cm³. The density of HfO₂ is 9.68 g/cm³. The density of Ta₂O₅ is 8.2 g/cm³. The density of WO₂ is 10.98 g/cm³. The density of ReO₃ is 6.92 g/cm³. The density of OsO₄ is 4.91 g/cm³. The density of IrO₂ is 11.66 g/cm³. The density of SrO is 4.7 g/cm³. The density of BaO is 5.72 g/cm³. The nitride of the metal may include, for example, YN, ZrN, NbN, HfN, TaN, or WN. Densities of these compounds are as described below. Specifically, the density of YN is 5.6 g/cm³. The density of ZrN is 7.09 g/cm³. The density of NbN is 8.47 g/cm³. The density of HfN is 13.8 g/cm³. The density of TaN is 13.7 g/cm³. The density of WN is 5.0 g/cm³. The boride of the metal may include, for example, BaB₆, YB₆, ZrB₂, NbB₂, TaB, HfB₂, WB, or ReB₂. Densities of these compounds are as described below. Specifically, the density of BaB₆ is 4.36 g/cm³. The density of YB₆ is 3.67 g/cm³. The density of ZrB₂ is 6.08 g/cm³. The density of NbB₂ is 6.97 g/cm³. The density of TaB is 14.2 g/cm³. The density of HfB₂ is 10.5 g/cm³. The density of WB is 15.3 g/cm³. The density of ReB₂ is 12.7 g/cm³. As described above, in terms of higher transmittance of the EUV light, the nitride of the metal is more preferable than the oxide of the metal, and the boride of the metal is more preferable than the nitride of the metal. When the second layer 62 contains the compound of the metal as described above, the thickness of the second layer 62 is preferably equal to or larger than a thickness of a minimum structural unit of the compound and 5 nm or smaller.

The second layer 62 may be arranged in contact with the multilayer film 42. In this case, the second layer 62 preferably does not contain a simple substance of a metal that is not a compound.

Such an EUV light reflective mirror 16 can be produced by, for example, repeating a deposition step several times to deposit the multilayer film 42, the second layer 62, and the first layer 61 in this order on a substrate 41. A depositing device may include, for example, a sputtering device, an atomic layer accumulating device, or the like. When the first layer 61 is deposited and then the deposited first layer 61 is annealed, the material of the first layer 61 is easily polycrystallized. Thus, the first layer 61 is preferably deposited and then annealed. When the material contained in the second layer 62 is to be polycrystallized, the second layer 62 is preferably deposited and then annealed like the first layer 61. The annealing may include laser annealing, and a laser beam used for the laser annealing may include, for example, a KrF laser beam, a XeCl laser beam, a XeF laser beam, or the like. A fluence of the laser beam is, for example, 300 to 500 mJ/cm², and a pulse width of the laser beam is, for example, 20 to 150 ns.

4.2 Effect

As described above, the hydrogen molecules contained in the gas supplied from the gas supply unit 18 are adsorbed on the surface 16A of the EUV light reflective mirror 16. When the hydrogen molecules are irradiated with light including EUV light generated when a droplet DL is turned into plasma in a plasma generating region PAL, the hydrogen molecules generate hydrogen radicals. The hydrogen radicals react with the tin fine particles moving toward the surface 16A of the EUV light reflective mirror 16 to generate stannane that is gas at room temperature.

In the EUV light reflective mirror 16 of this embodiment, the first layer 61 on an outermost side of the surface 16A contains the compound of the metal having lower electronegativity than Ti and the non-metal. This promotes the substitution reaction in Expression (1) for substituting the tin fine particles moving toward the surface 16A of the EUV light reflective mirror 16 with stannane to easily generate stannane. Thus, the EUV light reflective mirror 16 of this embodiment can prevent accumulation of the tin fine particles moving toward the surface 16A.

The first layer 61 has the lower density than TiO₂. This can reduce the tin fine particles moving toward the surface 16A of the EUV light reflective mirror 16 colliding with and wearing away the first layer 61 as compared to when the first layer 61 has a higher density than TiO₂. On the other hand, the tin fine particles more easily pass through the first layer 61 to reach the second layer 62 than when the first layer 61 has a higher density than TiO₂. However, the second layer 62 has the higher density than the first layer 61 as described above. Thus, even if the tin fine particles reach the second layer 62, the second layer 62 serves as a barrier to hold the tin fine particles on a surface of the second layer 62 or inside the second layer 62.

As such, the EUV light reflective mirror 16 of this embodiment can reduce passage of the tin fine particles through the first layer 61, also promote the substitution reaction of the tin fine particles with stannane, and hold the tin fine particles having passed through the first layer 61 on/in the second layer 62. Thus, the EUV light reflective mirror 16 of this embodiment can increase life of the first layer 61 and also prevent accumulation of the tin fine particles. In this way, the EUV light reflective mirror 16 that can prevent a reduction in reflectance of the EUV light can be achieved.

As described above, the second layer 62 of this embodiment has the higher density than the first layer 61, and thus can reduce passage of the hydrogen radicals as compared to when the second layer 62 has the lower density than the first layer 61. This can reduce the hydrogen radicals reaching the multilayer film 42. This can prevent occurrence of blister on an interface between the second layer 62 and the multilayer film 42.

When the second layer 62 of this embodiment contains the compound of the metal having lower electronegativity than Ti and the non-metal, the second layer 62 can promote the substitution reaction of the tin fine particles as compared to when the second layer 62 does not contain such a compound. Thus, even if the first layer 61 is worn away to expose the second layer 62, accumulation of the tin fine particles on the exposed second layer 62 can be prevented. This can further increase the life of the EUV light reflective mirror 16.

Electronegativities of Hf and Ta are lower than electronegativity of Ti, and densities of borides, nitrides, and oxides of Hf and Ta are higher than the density of TiO₂. Thus, when the second layer 62 contains at least one of the boride of Hf or Ta, the nitride of the metal, and the oxide of the metal, accumulation of the tin fine particles on the exposed second layer 62 can be prevented even if the second layer 62 is exposed as described above.

### 5. Description of EUV Light Reflective Mirror of Embodiment 2

Next, a configuration of an EUV light reflective mirror 16 of Embodiment 2 will be described. Components similar to those described above are denoted by the same reference numerals, and overlapping descriptions are omitted unless otherwise stated.

5.1 Configuration

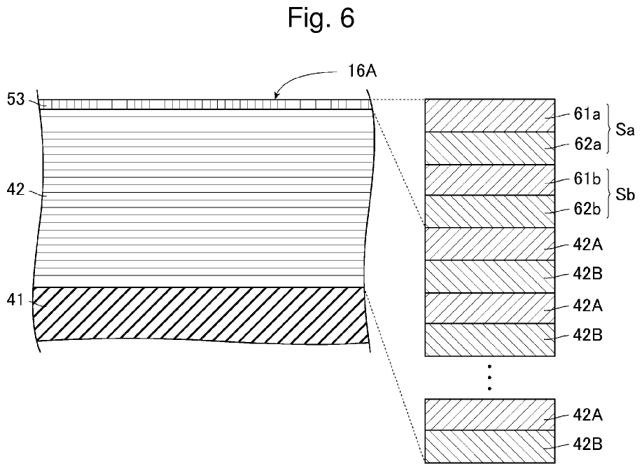

FIG. 6 diagrammatically shows a section of an EUV light reflective mirror 16 of Embodiment 2. As shown in FIG. 6, the EUV light reflective mirror 16 of this embodiment is different from the EUV light reflective mirror 16 of Embodiment 1 in that the former includes a plurality of first layers 61 and a plurality of second layers 62 while the latter includes one first layer 61 and one second layer 62.

In an example in FIG. 6, from a surface 16A toward a multilayer film 42, a first layer 61a, a second layer 62a, a first layer 61b, and a second layer 62b are stacked in this order. Each of the first layer 61a and the first layer 61b has the same configuration as that of the first layer 61 of Embodiment 1. Each of the second layer 62a and the second layer 62b has the same configuration as that of the second layer 62 of Embodiment 1. In this embodiment, the first layer 61a and the second layer 62a form a pair Sa, the first layer 61b and the second layer 62b form a pair Sb, and the two pairs Sa, Sb are arranged on the multilayer film 42. The number of the pairs of the first layer and the second layer is not limited to two, but may be three or more.

When the plurality of first layers and the plurality of second layers are provided as in this embodiment, a total thickness of the first layers 61a, 61b may be larger than a total thickness of the second layers 62a, 62b. However, the total thickness of the first layers 61a, 61b may be smaller than the total thickness of the second layers 62a, 62b.

Like the EUV light reflective mirror 16 of Embodiment 1, the EUV light reflective mirror 16 of this embodiment can be produced by, for example, repeating a deposition step several times using a depositing device such as a sputtering device or an atomic layer accumulating device.

5.2 Effect

As described above, hydrogen molecules contained in a gas supplied from a gas supply unit 18 are adsorbed on the first layer 61 of the top pair Sa farthest from the multilayer film 42 in the EUV light reflective mirror 16, and the hydrogen molecules are irradiated with light including EUV light to generate hydrogen radicals. Tin fine particles moving toward the surface 16A of the EUV light reflective mirror 16 react with the hydrogen radicals to generate stannane that is gas at room temperature.

The first layer 61a contains a compound of a metal having lower electronegativity than Ti and a non-metal as described above, and thus promotes the substitution reaction in Expression (1) to easily generate stannane. As described above, the first layer 61a has a lower density than TiO₂, and thus can reduce the tin fine particles colliding with and wearing away the first layer 61a. However, the tin fine particles may pass through the first layer 61a to reach the second layer 62a. The second layer 62a has a higher density than the first layer 61a as described above, and thus even if the tin fine particles reach the second layer 62a, the second layer 62a can serve as a barrier to hold the tin fine particles on a surface of the second layer 62a or inside the second layer 62a.

The tin fine particles may wear away the first layer 61a of the top pair Sa to locally expose the second layer 62a of the pair Sa from the first layer 61a, and the tin fine particles may further wear away the exposed second layer 62a to expose the first layer 61b of the second pair Sb. In this case, the first layer 61b of the second pair Sb also contains a compound of a metal having lower electronegativity than Ti and a non-metal, and thus promotes the substitution reaction in Expression (1) to easily generate stannane. As described above, the first layer 61b of the second pair Sb has a lower density than TiO₂, and thus can reduce the tin fine particles colliding with and wearing away the first layer 61b. On the other hand, the tin fine particles may pass through the first layer 61b to reach the second layer 62b. However, the second layer 62b has a higher density than the first layer 61b, and thus can hold the tin fine particles on a surface of the second layer 62b or inside the second layer 62b.

As such, in the EUV light reflective mirror 16 of this embodiment, the first layer and the second layer form the pair, and the plurality of pairs are stacked on the multilayer film 42. Thus, even if at least part of the first layer 61a and the second layer 62a of the pair Sa farthest from the multilayer film 42 are worn away, the substitution reaction of the tin fine particles with stannane can be promoted in the pair Sb closer to the multilayer film 42 than the pair Sa, and the tin fine particles can be prevented from reaching the multilayer film 42. Thus, the EUV light reflective mirror 16 of this embodiment can more reliably prevent accumulation of the tin fine particles and increase life of the EUV light reflective mirror 16 than the EUV light reflective mirror 16 of Embodiment 1 including one pair.

The above descriptions are intended to be illustrative only and not restrictive. Thus, it will be apparent to those skilled in the art that modifications may be made in the embodiments or variants of the present disclosure without departing from the scope of the appended claims.

The terms used throughout the specification and the appended claims should be interpreted as “non-limiting.” For example, the term “comprising” or “comprised” should be interpreted as “not limited to what has been described as being comprised.” The term “having” should be interpreted as “not limited to what has been described as having.” Further, the modifier “a/an” described in the specification and the appended claims should be interpreted to mean “at least one” or “one or more.”

What is claimed is:

1. A mirror for extreme ultraviolet light comprising:
a substrate;
a multilayer film provided on the substrate and configured to reflect extreme ultraviolet light; and
a capping layer provided on the multilayer film,
the capping layer including
a first layer containing a compound of a metal having lower electronegativity than Ti and a non-metal and having a lower density than TiO₂, and
a second layer arranged between the first layer and the multilayer film and having a higher density than the first layer.

2. The mirror for extreme ultraviolet light according to claim 1, wherein the first layer contains a compound of a group 2 element and a non-metal.

3. The mirror for extreme ultraviolet light according to claim 2, wherein the first layer contains at least one of a boride of the group 2 element, a nitride of the group 2 element, and an oxide of the group 2 element.

4. The mirror for extreme ultraviolet light according to claim 3, wherein the first layer contains the boride of the group 2 element.

5. The mirror for extreme ultraviolet light according to claim 1, wherein the first layer contains a compound of a metal selected from at least one of Mg, Ca, and Sc and a non-metal.

6. The mirror for extreme ultraviolet light according to claim 5, wherein the compound contained in the first layer is at least one of MgO, CaO, and ScO₃.

7. The mirror for extreme ultraviolet light according to claim 1, wherein a thickness of the first layer is larger than a thickness of the second layer.

8. The mirror for extreme ultraviolet light according to claim 1, wherein a thickness of the first layer is equal to or larger than a thickness of a minimum structural unit of the compound contained in the first layer and 5 nm or smaller.

9. The mirror for extreme ultraviolet light according to claim 1, wherein the capping layer includes a plurality of pairs of the first layer and the second layer, and the plurality of pairs are arranged on the multilayer film.

10. The mirror for extreme ultraviolet light according to claim 9, wherein a total thickness of the first layers of the pairs is larger than a total thickness of the second layers of the pairs.

11. The mirror for extreme ultraviolet light according to claim 1, wherein the second layer contains a compound of a metal having lower electronegativity than the electronegativity of Ti and a non-metal.

12. The mirror for extreme ultraviolet light according to claim 11, wherein the compound contained in the second layer has a polycrystalline structure.

13. The mirror for extreme ultraviolet light according to claim 11, wherein a thickness of the second layer is equal to or larger than a thickness of a minimum structural unit of the compound contained in the second layer and 5 nm or smaller.

14. The mirror for extreme ultraviolet light according to claim 1, wherein the second layer contains at least one of a boride of a lanthanoid metal, a nitride of the lanthanoid metal, and an oxide of the lanthanoid metal.

15. The mirror for extreme ultraviolet light according to claim 14, wherein the thickness of the second layer is equal to or larger than a thickness of a minimum structural unit of the compound of the lanthanoid metal contained in the second layer and 5 nm or smaller.

16. The mirror for extreme ultraviolet light according to claim 1, wherein the second layer contains at least one of a boride of Y, Zr, Nb, Hf, Ta, W, Re, Os, Ir, Sr, or Ba, a nitride of Y, Zr, Nb, Hf, Ta, W, Re, Os, Ir, Sr, or Ba, and an oxide of Y, Zr, Nb, Hf, Ta, W, Re, Os, Ir, Sr, or Ba.

17. The mirror for extreme ultraviolet light according to claim 16, wherein a thickness of the second layer is equal to or larger than a thickness of a minimum structural unit of the compound of the metal contained in the second layer and 5 nm or smaller.

18. The mirror for extreme ultraviolet light according to claim 16, wherein the second layer contains at least one of the boride of Hf or Ta, the nitride of Hf or Ta, and the oxide of Hf or Ta.

19. The mirror for extreme ultraviolet light according to claim 1, wherein the second layer contains at least one of La₂O₃, CeO₂, Eu₂O₃, TmO₃, Gd₂O₃, Yb₂O₃, Pr₂O₃, Tb₂O₃, Lu₂O₃, Nd₂O₃, Dy₂O₃, Pm₂O₃, Ho₂O₃, Sm₂O₃, Er₂O₃, SmN, TmN, YbN, LaB₆, CeB₆, NdB₆, SmB₆, Y₂O₃, ZrO₂, Nb₂O₅, HfO₂, Ta₂O₅, WO₂, ReO₃, OsO₄, IrO₂, SrO, BaO, YN, ZrN, NbN, HfN, TaN, WN, BaB₆, YB₆, ZrB₂, NbB₂, TaB, HfB₂, WB, and ReB₂.

20. An extreme ultraviolet light generating apparatus: comprising:
a chamber;
a droplet discharge unit configured to discharge a droplet of a target substance into the chamber; and
a mirror for extreme ultraviolet light provided in the chamber,
the mirror for extreme ultraviolet light including a substrate, a multilayer film provided on the substrate and configured to reflect extreme ultraviolet light, and a capping layer provided on the multilayer film,
the capping layer including a first layer containing a compound of a metal having lower electronegativity than Ti and a non-metal and having a lower density than TiO₂, and a second layer arranged between the first layer and the multilayer film and having a higher density than the first layer.
